(19) United States
(12) Patent Application Publication
(10) Pub. No.: US 2021/0188516 A1
(43) Pub. Date: Jun. 24, 2021

(54) WAFFLE PACK FOR DEVICE CONTAINMENT

(71) Applicants: BAE Systems Information and Electronic Systems Integration Inc., Nashua, NH (US); Delphon Industries, LLC, Hayward, CA (US)

(72) Inventors: Richard Rochford, Litchfield, NH (US); Edward L. Brabant, JR., Dracut, MA (US); Donald M. Bascos, Fremont, CA (US); Darby A. Davis, Sherwood, OR (US)

(21) Appl. No.: 17/270,534

(22) PCT Filed: Nov. 20, 2019
(86) PCT No.: PCT/US2019/062463

§ 371 Date: Feb. 23, 2021

Related U.S. Application Data
(60) Provisional application No. 62/769,899, filed on Nov. 20, 2018.

(51) Int. Cl. B65D 81/133; H01L 21/673; B65D 81/127; B65D 85/38

(52) U.S. Cl. CPC B65D 81/133; H01L 21/67333; B65D 2213/02; B65D 85/38; B65D 81/1275

(57) ABSTRACT

A system for securely storing semiconductor die and devices employing a waffle pack lid configured to mate with a waffle pack tray. The lid body has an interior surface with a cavity including a shock absorbing layer. There is at least one electrostatic dissipative layer comprising attached to the shock absorbing layer such that the electrostatic dissipative layer seals the compartments on the waffle pack tray.

### CROSS REFERENCE TO RELATED APPLICATIONS

This application claims the benefit of U.S. Application Ser. No. 62/769,899 entitled Waffle Pack Lid for Device Containment filed Nov. 20, 2018; the entire disclosure of which is incorporated herein by reference.

### FIELD

The present disclosure relates generally to waffle packs for packaging of semiconductor devices.

### BACKGROUND

Waffle packs are typically used for the shipping and handling of small electrical devices, including, but not limited to, thin die for integrated circuits. Conventional waffle packs include a tray, a lid, and a clip for securing the lid to the tray. Shipping thin die in waffle packs presents a challenge for many companies in the semiconductor industry. Die are very fragile and can be damaged by the jostling of shipping and handling. Even the slightest bump can move the die and potentially lead to a shortened lifespan, increased failures, or render them inoperable. Waffle pack trays typically have a base portion with compartments (also referred to as pockets or cavities) that house individual die to minimize jostling and damage during transport and generally have a lid to keep dust and other particles from contaminating the die. However, displacement of the die, sometimes referred to as, “die out of pocket,” is common in the industry. The die are small and have a tendency to be displaced from their compartments (called “die out of pocket”) during transport, which causes the mingling of parts and potential damage. Damaged devices lead to poor inventory control and increased costs to replace the damaged devices. Although various designs exist for the pocket of the trays, displacement and damage to the die still exists.

Conventional waffle pack lids typically involve a hard plastic lid covering the base portion and compartments. One difficulty with the conventional lid is that the hard plastic does not provide adequate protection of the die within the tray, nor does it provide prevention of die displacement during shipping and handling. One existing solution was to employ an adhesive in each compartment. This solution has a number of issues with residue and damaging the die during removal.

Some conventional lids involve a lid with a thick, foam pad such as closed cell foam, which may not prevent damage due to its lack of shock absorbing characteristics. Additionally, die may also stick to the foam and then become displaced and damaged in the waffle pack. The traditional layer tends to be a source of foreign object debris (FOD) that may impact part functionality or part life. It may also provide a surface for the electrical components to stick to and then become displaced and damaged in the waffle pack. This layer may also have properties such as outgassing that may affect the devices in the compartments of the waffle pack trays.

Some hard plastic lids involve the placement of an electrostatic dissipative sheet(s) between the lid and the tray. The electrostatic dissipative sheets easily become misaligned with the tray during the placement and opening/closing of the lid. The misalignment of the electrostatic dissipative sheet causes a misalignment of the tray and lid, which facilitates the displacement and thus, damage, of the die.

Conventional waffle packs involve the use of a single clip that is independent of the tray and lid, which holds the tray and lid together but does not adequately secure or seal the tray and lid together. The clip bends and warps the waffle pack, which creates space for the die to migrate out of their respective pockets. Additionally, a clip is typically removed from the waffle pack to retrieve a die and then used again to close the waffle pack containing the remaining die. Each time a clip is re-used, the clip exerts less clamping force on the waffle pack, which makes the closed waffle pack less secure, causing misalignment of the tray and lid, and thus facilitating displacement of the die.

### SUMMARY

Accordingly, there is a need for an improved lid and attachment mechanism that prevents the die from becoming displaced from its pocket and damaged during shipping and handling and overcome the aforementioned concerns.

An example embodiment of the present disclosure provides a system for a waffle pack lid configured to mate with a waffle pack tray that includes a body comprising an exterior surface and an interior surface with inner walls forming an interior cavity. There is a shock absorbing layer attached to the interior cavity on a first side of the shock absorbing layer and at least one electrostatic dissipative (ESD) layer attached to a second side of the shock absorbing layer, wherein the ESD layer engages the waffle pack tray when mated to seal a plurality of compartments in the waffle pack tray.

Particular implementations may include one or more of the following features. The waffle pack lid may be configured to mate with a conventional 2-inch or 4-inch waffle pack tray. The shock absorbing layer and the ESD layer may be substantially the same size. Two or more angled sections of the body may engage with corresponding angled sections of the waffle pack tray. The waffle pack lid may slide along the angled sections via an open section of the body. An attachment mechanism for the mated waffle pack lid and tray may include at least four walls, wherein at least three walls comprise a continuous peripheral side wall, and at least one wall may have an opening for the waffle pack to slidably engage with the continuous peripheral side wall. The lid may include two more captivating legs that slidably engage with the tray.

An example embodiment of the present disclosure provides a system for a waffle pack lid configured to mate with a waffle pack tray that includes a body including an exterior surface and an interior surface; at least one electrostatic dissipative (ESD) layer including a first side attached to the interior side and a second side proximate the waffle pack tray when mated; and an adhesive layer bonding the interior surface of the body to the first side of the ESD layer.

Particular implementations may include one or more of the following features. The electrostatic dissipative layer may be secured at least about a periphery of the interior side. The waffle pack tray may include a plurality of semiconductor devices placed in compartments. The lid may include two or more captivating legs that slidably engage with the tray.

An example embodiment of the present disclosure provides a method for packaging of semiconductor devices that includes providing a plurality of semiconductor devices in compartments in a waffle pack tray; placing a lid on the waffle pack tray, wherein the lid includes an electrostatic dissipative layer coupled to the interior of the lid; and securing the lid to the waffle pack tray.

Particular implementations may include one or more of the following features. The lid may be removed from the waffle pack tray by sliding the lid off the waffle pack tray. The electrostatic dissipative layer may include a conductive PS carbon material. The lid may include a shock absorbing layer coupled to the interior of the lid and the electrostatic dissipative layer coupled to the shock absorbing layer.

Implementations of the techniques discussed above may include a method or process, a system or apparatus. The details or one or more implementations are set forth in the accompanying drawings and the description below. Other features will be apparent from the description and drawings, and from the claims.

The features and advantages described herein are not all-inclusive and, in particular, many additional features and advantages will be apparent to one of ordinary skill in the art in view of the drawings, specification, and claims. Moreover, it should be noted that the language used in the specification has been selected principally for readability and instructional purposes and not to limit the scope of the inventive subject matter.

### BRIEF DESCRIPTION OF THE DRAWINGS

FIG. 1A is a cross-sectional view depicting the waffle pack lid in accordance with an embodiment.

FIG. 1B is a cross-sectional view of the waffle pack lid in accordance with another embodiment.

FIG. 1C is a cross-sectional view of the waffle pack lid in accordance with a further embodiment.

FIG. 2A is a cross-sectional view depicting the mating/coupling of the waffle pack lid to the waffle pack tray in accordance with an embodiment.

FIG. 2B is a cross-sectional view depicting the mating/coupling of the waffle pack lid to the waffle pack tray in accordance with an embodiment.

FIG. 3 is a cross-sectional view depicting the mating/coupling of the waffle pack lid to the waffle pack tray in accordance with an alternative embodiment.

FIG. 4A is a perspective view of the waffle pack attachment mechanism in accordance with one embodiment.

FIG. 4B is a bottom view perspective of the waffle pack attachment mechanism of FIG. 4A.

FIG. 5 is a perspective view of the waffle pack attachment mechanism in accordance with an alternative embodiment.

FIG. 6 is a flow diagram of a method for packaging of semiconductor devices.

These and other features of the present embodiments will be understood better by reading the following detailed description, taken together with the figures herein described. The accompanying drawings are intended to be drawn to scale. For purposes of clarity, not every component may be labeled in every drawing.

### DETAILED DESCRIPTION

The present disclosure relates to waffle packs for semiconductor device packaging. More particularly, a system for a waffle pack lid. The following description focuses on waffle pack lids and an attachment mechanism to secure the waffle pack lid and base that are suitable for the prevention of displacement and damage of small electrical devices contained within the waffle pack during shipping and handling. By way of example, small electrical devices may include integrated circuit die, and generally, any electrostatic sensitive device (ESD). Various embodiments of the present disclosure will be described herein.

A conventional waffle pack system has a tray with a number of individual compartments (also referred to as pockets or cavities) for holding semiconductor components, such as die. The size, shape, and number of compartments are configured according to the design criteria for holding the semiconductor components, but typically waffle packs are square and in 2-inch and 4-inch sizes.

A conventional waffle pack system has a lid that mates with the tray. One or more electrostatic dissipative sheets may be placed onto the top of the tray to cover the devices. After laying the sheet, the lid is placed on top of the sheet. One known issue with this assemblage is that the sheet tends to move during the placement of the sheet, placement of the lid, or during shipping or handling.

The electrostatic dissipative sheets can become misaligned with the tray and lid when they move during placement or during shipping or handling, which provides a misalignment of the tray and lid, facilitating the displacement and damage of the semiconductor components. It may also prevent the lid from being properly secured to the tray.

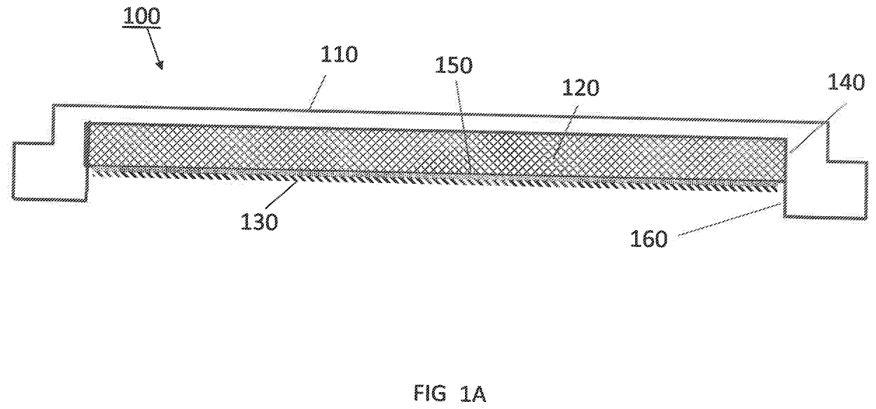

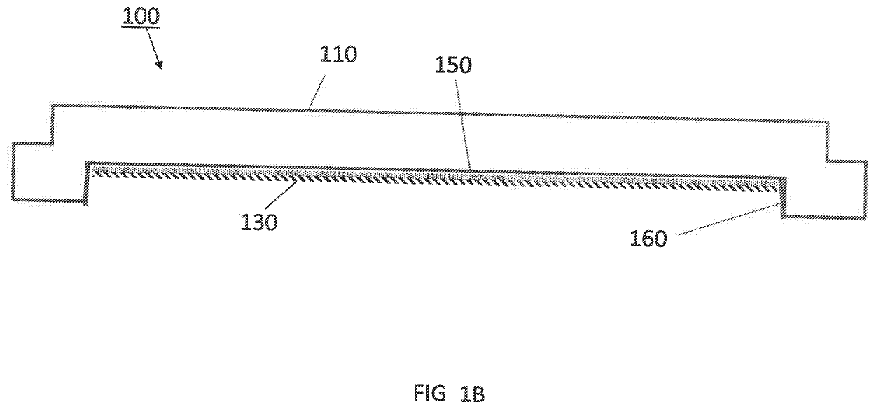

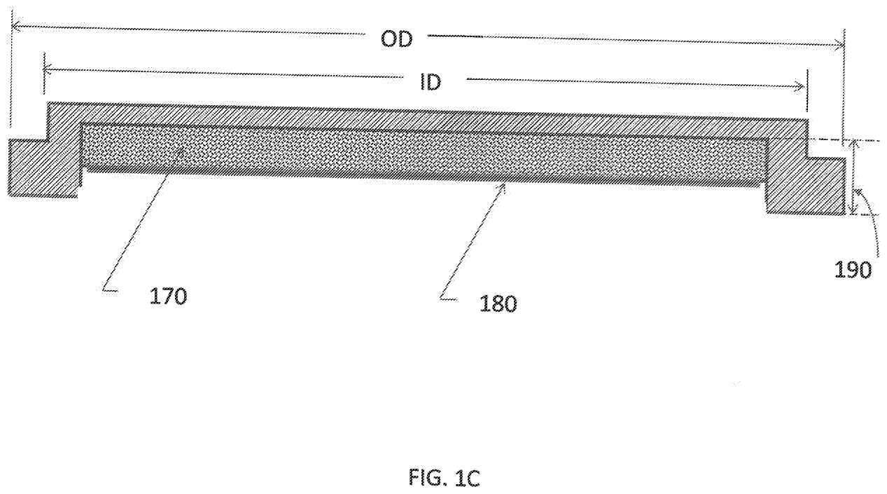

FIG. 1A is a cross-sectional view of a waffle pack lid 100 according to one embodiment. The waffle pack lid 100 has a body 110, a shock absorbing layer 120, and an electrostatic dissipative layer 130. One skilled in the art will appreciate that the size and shape of waffle packs may vary to accommodate the number, size, shape, and arrangement of small electrical components in the waffle pack. The waffle pack lid 100 may be of a wide variety of shapes and sizes, customized to carry a wide variety of small electrical components, and generally, any that are subject to electrostatic discharge (ESD) concerns. In one embodiment, the waffle pack lid 100 may be 2×2 or 4×4 inches and configured to mate with a corresponding waffle pack tray (not shown). The body 110 may be formed from any anti-static or ESD suitable material to prevent damage of the electrical components caused by electrostatic discharge while creating a safe enclosure for the valuable components contained therein. By way of example, the body 110 may be formed from plastic such as a polycarbonate or antistatic acrylonitrile butadiene styrene with ESD protection.

In various embodiments, the body 110 may include interior walls 160 defining a cavity or recess 140 that houses the shock absorbing layer 120. The shock absorbing layer 120 may have the same general shape as the recess 140 or otherwise occupy the space in the cavity 140. The waffle pack lid 100 may be planar, wherein the shock absorbing layer 120 may be contiguous with the periphery of the body 110. In one embodiment, a 2-inch waffle pack lid may include a recess 140 that has the dimensions of 1.78 inches×1.78 inches.

In one example, the electrostatic dissipative layer 130 is attached to the shock absorbing layer 120 to meet the highest industry standards for ESD and FOD to prevent contamination of the die and the die sticking to the shock absorbing layer 120.

By way of example, the electrostatic dissipative layer 130 may be formed from an interleaf material, including but not limited to high-density polyethylene fibers or conductive PS carbon separator material. By way of example, the interleaf material may be eM 20, which is a conductive PS carbon separator material from ePAK® that provides a lint free material and ESD shielding as well as electromagnetic interference (EMI) shielding.

The shock absorbing layer 120 may be formed from a suitable shock absorbing material to protect the die within the waffle pack. By way of example, the shock absorbing layer 120 may be formed from microcellular polyurethane foam.

In various embodiments, the shock absorbing layer 120 is attached to the body 110 by one or more adhesive layers 150 and the electrostatic dissipative layer 130 is attached to the shock absorbing layer 120 by the adhesive layer 150. The adhesive layer 150 may be formed from any material that meets ESD industry standards and in one example the adhesives 150 are the same. By way of example, the adhesive layers 150 in one example is a polyester film adhesive. The adhesive layers 150 respectively are attached to the shock absorbing layer 120, the electrostatic dissipative layer 130, and to the body 110 by any suitable method, including, but not limited to spraying, rolling, a cut adhesive sheet activated by heat, and the like. In one example the adhesive layer 150 for the electrostatic dissipative layer 130 has adhesive around at least a periphery of the layer so that it completely covers the shock absorbing layer 120.

In one example, a sheet of adhesive may be placed between a sheet of shock absorbing material and an electrostatic dissipative sheet. The shock absorbing material, adhesive, and electrostatic dissipative sheet may be laminated together by heat to produce an integral shock absorbing layer 120 with the electrostatic dissipative layer 130. Then, the integral shock absorbing layer 120 with the electrostatic dissipative layer 130 may be cut to the dimensions for the body 110 that is configured to be used therewith. Adhesion of the shock absorbing layer 120 and the electrostatic dissipative layer 130 prevents misalignment of the two layers within the space of the waffle pack between the lid 100 and tray 200. This adhesion also prevents misalignment of the lid 100 to the tray 200, which reduces the likelihood that the devices will be displaced from their compartments and damaged.

In various embodiments, the electrostatic dissipative layer 130 is attached to the shock absorbing layer 120 such that both layers may be housed within the recess 140 of the lid body 110. The shock absorbing layer 120 and the electrostatic dissipative layer 130 may be substantially the same size. In various embodiments, the shock absorbing layer 120 and the electrostatic dissipative layer 130 may be approximately the same size as the lid 100. In alternative embodiments, the shock absorbing layer 120 and the electrostatic dissipative layer 130 may be approximately the size of the area of the tray 200 to contact the top of each compartment. In one example the electrostatic dissipative layer 130 creates a seal around each compartment in the tray.

In an alternative embodiment shown in FIG. 1B, the lid 100 has a body 110 and an electrostatic dissipative layer 130, which is attached to the underside body of the lid 110. The interior wall 160 can extend further to reduce the size of the cavity and bring the electrostatic dissipative layer 130 closer to the semiconductor devices in the mated waffle pack tray. In an alternative embodiment, the electrostatic dissipative layer 130 is thicker and there is no shock absorbing layer.

A further embodiment is depicted in FIG. 1C, wherein the shock absorbing layer is high density (HD) Microcellular Urethane 170. It can fit within the cavity that in certain standard size 2 inch waffle packs would measure about 1.73 inches×1.73 inches×0.093 inches. The electrostatic dissipative layer 180 in one example is carbon-filled polystyrene and in a 2 inch waffle pack could measure 1.73 inches×1.73 inches×0.005 inches. In one example for the 2 inch waffle pack, the outer dimensions (OD) would measure 2 inches and the inner dimensions (ID) measure 1.8 inches.

The cavity distance 190 from the interior of the lid to the lower edge of the body represents the distance that is typically filled with the shock absorbing material such that when compressed, the ESD layer seals the compartments in the waffle pack.

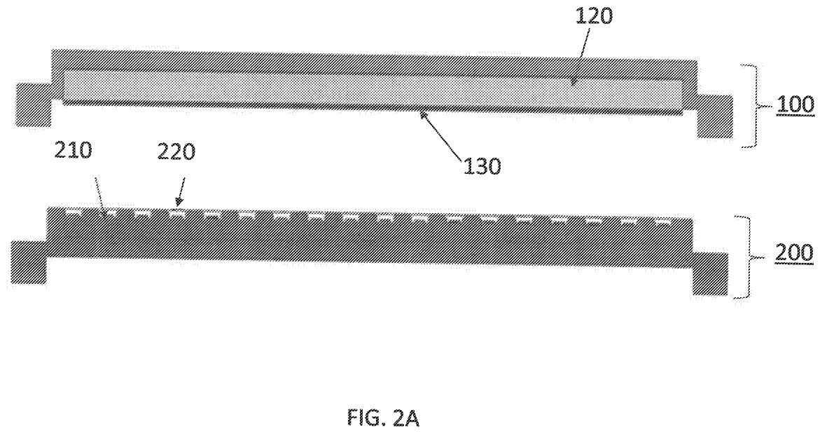

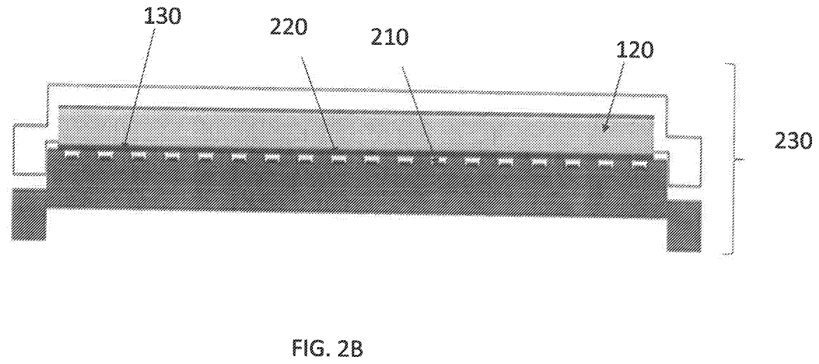

FIG. 2A and FIG. 2B are cross-sectional views depicting the mating of the waffle pack lid 100 to the waffle pack tray 200. The waffle pack tray 200 has die 210 positioned within their associated compartment 220. In various embodiments, the shock absorbing layer 120 fills the space between the top of the compartment and the lid body 110, which secures the die 210 within its respective compartment 220 to prevent misalignment and displacement outside of their intended compartment 220 during shipping and handling. Additionally, the shock absorbing layer 120 absorbs shock from the jostling during shipping and handling to further protect the die 210 within their compartments 220.

In a mated waffle pack 230 (FIG. 2B), the electrostatic dissipative layer 130 contacts the top of the compartments 220 and seals every compartment as there is adequate pressure from the shock absorbing layer 120 so that the ESD layer 130 is in contact with the top of the compartments. The combined thickness of the ESD layer 130 and shock absorbing layer 120 are to allow sealing of the compartments when pressure is applied when mated, but prevents further deflection of the ESD layer 130 to push the ESD layer 130 into the compartments. In addition to sealing the compartments to prevent the devices from migration, the ESD layer 130 also protects the die 210 from sticking as well as providing greater ESD and outgassing protection.

In one example, the waffle pack lid engages with the waffle pack tray in the known manner and slidably engages such that the lid is pushed into position thereby covering the compartments in the tray. The lid is configured to mate with the waffle pack tray and in one example there are angled sections on the lid that mate with corresponding angled sections on the tray. Once the lid angled sections are mated to the tray angled sections, the mated waffle pack tray and lid can be fastened or otherwise secured by the attachment mechanism. In one example, there are angled sections on one side of the mated waffle pack tray and lid. In another example, the angled sections are on three sides with one side being open such that the lid can be slid for removal via the open side. The angled sections of the lid and the angled sections of the tray facilitate the mating of the waffle pack and reduces the likelihood of displacement of the die from their compartments.

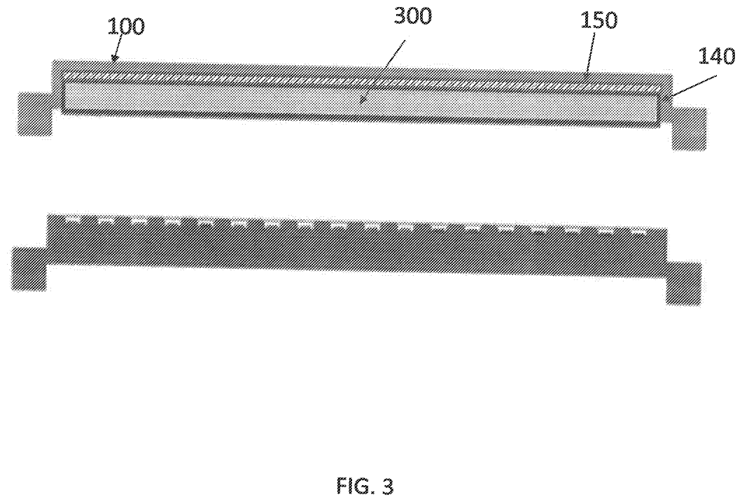

Referring to FIG. 3, a further embodiment includes the lid body 110 extending further into the lid recess 140. The thicker electrostatic dissipative layer 300 in this example is secured directly to the interior cavity 140. There is no need for an additional shock absorbing layer as the functionality is accommodated by the thicker electrostatic dissipative layer 300. For example, there may be multiple electrostatic dissipative sheets that provide the appropriate cushioning effect or the electrostatic sheets can form an enclosed member having foam in the middle. The electrostatic dissipative layer 300 may be attached to the interior of the lid body 110 by one or more adhesive layers 150. In one example, the electrostatic dissipative layer 300 may be attached to the periphery of the interior side of the lid body 110. In another example, the electrostatic dissipative layer 300 may be attached within the lid recess 140.

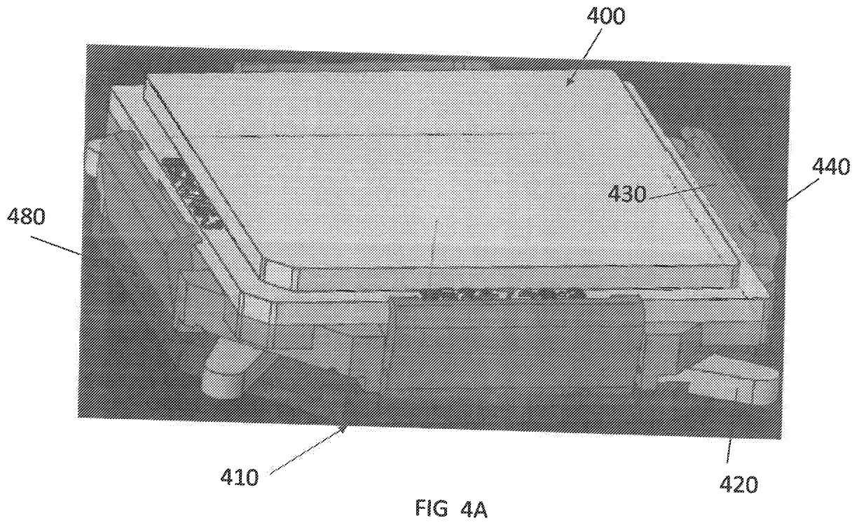

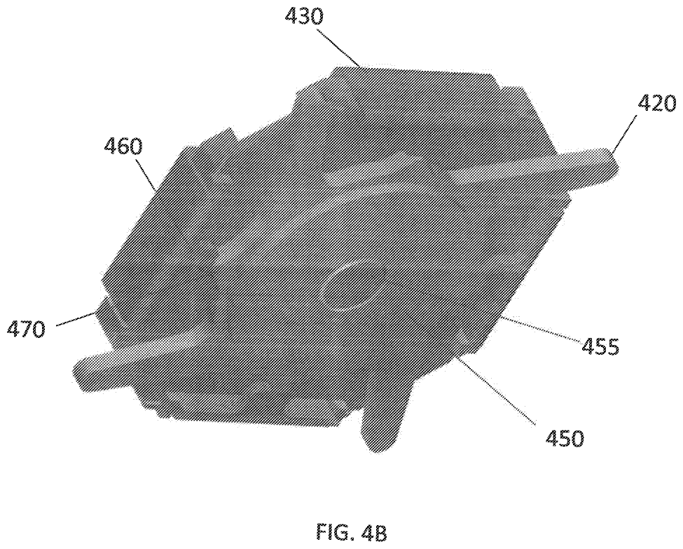

Referring to FIG. 4A and FIG. 4B, the mated waffle pack tray and lid 400 are secured by the attachment mechanism 410. As detailed herein, the lid includes the electrostatic dissipative layer and protects the semiconductor devices in the waffle pack. The lid is configured to mate with the waffle pack tray and in one example there are angled sections on the lid that mate with corresponding angled sections on the tray. Once the lid is mated to the tray, the mated waffle pack tray and lid 400 can be fastened or otherwise secured by the attachment mechanism 410.

In one example, the attachment mechanism 410 has a base 480 with at least two extended captivating legs 420 attached to the base 480. The captivating legs 420 are moveable to engage and disengage retention clips 430 by rotating the captivating legs 420. The retention clips 430 in one example have extended portions 440 that have an angular profile such that that engage with the waffle pack lid and apply uniform pressure as they grab the waffle pack. The lid and tray 400 may be placed into the attachment mechanism 410 by placing the lid and tray 400 upon the attachment mechanism 410 and then rotating the captivating legs 420 that deploy the retention clips 430. In one example there are two retention clips and in the illustrated example there are four retention clips 430. By engaging the retention clips as detailed herein, the attachment mechanism 410 provides uniform compression that reduces the likelihood of displacement and damage of the devices in the waffle pack.

As illustrated in FIG. 4B, the captivating legs 420 extend from a common central unit 450 that is rotatable about a hub 455 such that the captivating legs 420 move in unison to engage/disengage the retention clips 430. The central unit 450 includes a nub or protrusion 470 that engages with a retention clip protrusion 460 such that it operates like a cam to open and close the retention clips as the captivating legs 420 are moved.

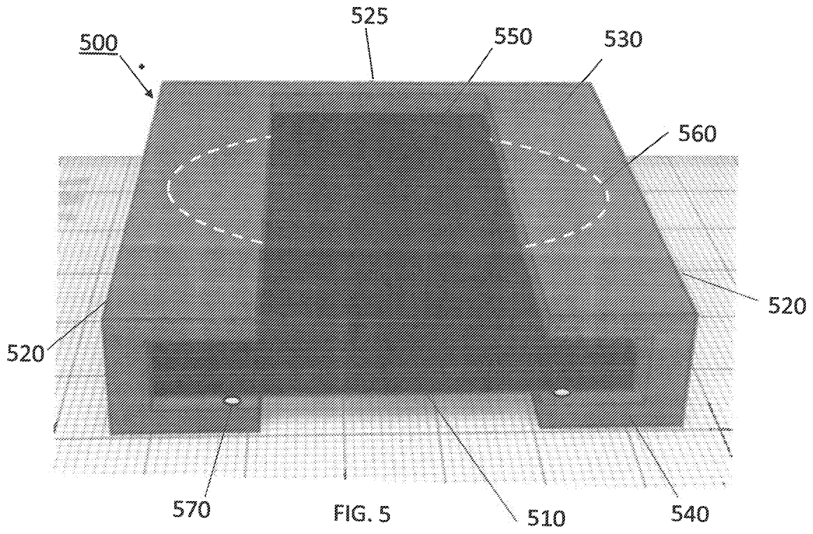

Referring to FIG. 5, the waffle pack attachment mechanism or holder 500 may have a continuous peripheral left and right side walls 520 with a rear side wall 525 with a top and bottom integral covers 530. A front side 540 is at least partially open such that the mated waffle pack 510 slides into the opening and is secured by the three peripheral walls and the top and bottom covers. This maintains a uniform distribution of pressure onto the waffle pack 510 and ensures that the interior shock absorbing material exerts adequate pressure so the electrostatic dissipative layer contacts the tray compartments so the devices therein remain in the appropriate compartments. By maintaining the mated waffle pack 510 in the holder 500 there is less likelihood of displacement of the devices. In one example, there is a cut-out region 550 on at least one of the top and bottom to allow for easy placement and retrieval of the mated waffle pack 510. In one example, the waffle pack 510 can be retrieved by grasping between the thumb and index finger and extracted from the holder. The dimensions of the fastener 500 depend upon the size of the mated waffle pack and in one example completely receives the mated waffle pack 510 so that it maintains continuous and uniform pressure on the mated waffle pack.

In many instances, it is useful to view the top and/or bottom of the waffle pack 510 for information on the devices within the waffle pack. In one embodiment, additional cut-out regions 560 on the top and/or bottom can allow greater area for viewing of the information displayed on the waffle pack whether printed on the waffle pack or on a label. In one example, the label is designed to fit within the cut-out regions 500, 560.

The sizing of the interior dimensions of the holder 500 in one embodiment is to allow for a friction fit of the waffle pack 510 so that it is maintained within the holder and does not easily slip out. In one further example, a lip or protrusion 570 is located at the front 540 of the waffle pack 510 so that it is easier to confirm the waffle pack is properly positioned within the holder 500 and adds additional protection from the waffle pack being displaced from the holder 500.

According to one example, the holder is injection molded as an integral unit in order to reduce cost of an individual unit. The holder can be a plastic material such as a polycarbonate or antistatic acrylonitrile butadiene styrene with ESD protection. In one example, the material is Permastat 600 plus. In one example, the plastic material is relatively clear or otherwise translucent such that any information on the waffle pack is visible without having to rely on large cut-out regions.

Certain conventional holders apply pressure on the two side edges of the waffle pack 510 that can lead to warping and bending of the holder that allows the components in the compartments to migrate since there is inadequate uniform pressure. The conventional holders in some examples may include leaf springs on the lower surface applying pressure, however the pressure is uneven since the retention mechanism is on the two side edges of the waffle pack. Embodiments of the present holder avoid these problems in the conventional art by employing the fixed electrostatic dissipative layer along with a shock absorbing layer that forms a seal around each compartment when closed and held in a holder device.

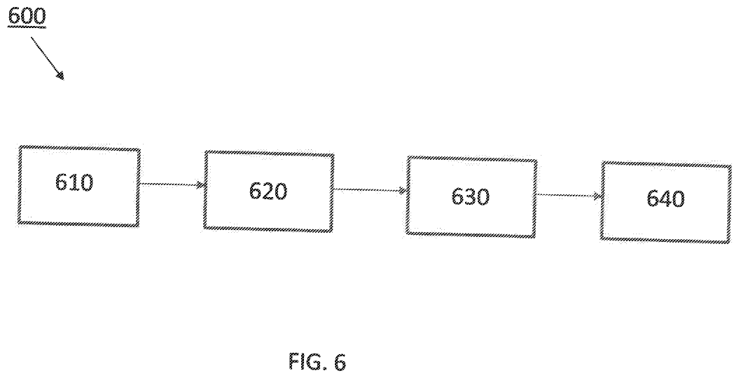

Turning now to FIG. 6, there is shown a method for packaging semiconductor devices 600. This method may include providing a plurality of semiconductor devices in compartments in a waffle pack tray 610. This method may also include placing a lid on the waffle pack tray 620. In one example, the lid may have an electrostatic dissipative layer attached to the interior of the lid. In another example, the lid may have a shock absorbing layer attached to the interior of the lid and an electrostatic dissipative layer attached to the shock absorbing layer. The method may also include securing the lid to the waffle pack tray 630. The method may also include removing the lid from the waffle pack tray by sliding the lid off the waffle pack tray 640.

The foregoing description of the embodiments of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

1. A waffle pack lid configured to mate with a waffle pack tray, the waffle pack lid comprising:
a body comprising an exterior surface and an interior surface with inner walls forming an interior cavity;
a shock absorbing layer attached to the interior cavity on a first side of the shock absorbing layer; and
at least one electrostatic dissipative (ESD) layer attached to a second side of the shock absorbing layer, wherein the ESD layer engages the waffle pack tray when mated to seal a plurality of compartments in the waffle pack tray.

2. The waffle pack lid of claim 1, further comprising an adhesive layer bonding the ESD layer to the second side of the shock absorbing layer.

3. The waffle pack lid of claim 1, wherein the waffle pack lid is configured to mate with a 2-inch or 4-inch waffle pack tray.

4. The waffle pack lid of claim 1, further comprising an adhesive layer bonding the shock absorbing layer to the interior cavity.

5. The waffle pack lid of claim 1, wherein the shock absorbing layer is a microcellular polyurethane foam or a high density (HD) microcellular urethane.

6. The waffle pack lid of claim 1, wherein the shock absorbing layer and electrostatic dissipative layer are laminated together to produce an integral shock absorbing layer with the ESD layer.

7. The waffle pack lid of claim 1, wherein the ESD layer comprises a conductive PS carbon or high-density polyethylene.

8. The waffle pack lid of claim 1, further comprising a holder, wherein the holder comprises a rear wall, two side walls, and a front wall with an opening to receive a mated waffle pack lid and waffle pack tray.

9. The waffle pack lid of claim 1, further comprising a holder, wherein the holder comprises at least two retention clips to secure a mated waffle pack lid and waffle pack tray.

10. A waffle pack lid configured to mate with a waffle pack tray, comprising:
a plastic body comprising an exterior surface and an interior surface with inner walls forming an interior cavity;
at least one electrostatic dissipative (ESD) layer attached within the interior cavity; and
an adhesive layer bonding the ESD layer to the interior cavity.

11. The waffle pack lid of claim 10, wherein the ESD layer is secured about a periphery of the interior side.

12. The waffle pack lid of claim 10, wherein the ESD layer is a conductive PS carbon material.

13. The waffle pack lid of claim 10, wherein the waffle pack tray comprises a plurality of semiconductor devices placed in compartments, wherein the ESD layer seals the compartments when mated to the lid.

14. The waffle pack lid of claim 13, wherein the electrostatic dissipative layer is carbon-filled polystyrene.

15. A device for packaging of semiconductor devices, comprising,
a waffle pack lid having an exterior surface and an interior surface with inner walls forming an interior cavity;
a shock absorbing layer attached to the interior surface;
at least one electrostatic dissipative (ESD) layer attached to the shock absorbing layer; and
a waffle pack tray having a plurality of compartments for the semiconductor devices and configured to mate with the waffle pack lid.

16. The device of claim 15, further comprising a holder, wherein the holder comprises a rear wall, two side walls, and a front wall with an opening to receive the mated waffle pack lid and waffle pack tray and apply uniform pressure so the shock absorbing layer has some compression and the ESD layer seals the compartments.

17. The device of claim 15, further comprising a holder, wherein the holder comprises at least two retention clips configured to deploy in unison by rotating captivating legs to secure the mated waffle pack lid and waffle pack tray and apply uniform pressure so the shock absorbing layer has some compression and the ESD layer seals the compartments.
